(19) United States
(12) Patent Application Publication
(10) Pub. No.: US 2014/0252438 A1
(43) Pub. Date: Sep. 11, 2014

(54) Three-Dimensional Magnetic Random Access Memory With High Speed Writing

(71) Applicant: Alexander Mikhailovich Shukh, Savage, MN (US)

(72) Inventor: Alexander Mikhailovich Shukh, Savage, MN (US)

(21) Appl. No.: 13/792,157

(22) Filed: Mar. 10, 2013

(51) Int. Cl. H01L 43/02

(52) U.S. Cl. CPC H01L 43/02
USPC 257/295

(57) ABSTRACT

One embodiment of a magnetic random access memory includes a magnetic memory cell comprising a transistor disposed on a substrate, electrically coupled to a first conductive line and comprising a gate width; a plurality of magnetoresistive elements, each magnetoresistive element comprising an element width, a pinned magnetic layer comprising a fixed magnetization direction directed perpendicular to the substrate, a free magnetic layer comprising a reversible magnetization direction directed perpendicular to the substrate, and a tunnel barrier layer residing between the pinned and free layers; and a plurality of parallel second conductive lines overlapping the first conductive line. The plurality of the parallel second lines is independently electrically coupled to the plurality of magnetoresistive elements at first terminals, and the plurality of magnetoresistive elements is jointly electrically coupled to the transistor at second terminals, wherein the gate width is substantially larger than the element width. Other embodiments are described and shown.

### CROSS-REFERENCE TO RELATED APPLICATION

This application is a division of U.S. patent application Ser. No. 12/837,503, filed on Jul. 16, 2010, which claims benefit of U.S. Provisional Patent Application No. 61/227,364 filed on Jul. 21, 2009, which are hereby incorporated by reference in their entirety.

### FEDERALLY SPONSORED RESEARCH

Not Applicable

### SEQUENCE LISTING OR PROGRAM

Not Applicable

### FIELD OF THE APPLICATION

The present application relates to a magnetic random access memory (MRAM) and, more specifically, to a perpendicular MRAM with high-speed writing that can be arranged in a three-dimensional architecture.

### BACKGROUND

Magnetic random access memory (MRAM) is a new memory technology that will likely provide a superior performance over existing semiconductor memories including flash memory and may even replace hard disk drives in certain applications requiring a compact non-volatile memory device. In MRAM bit of data is represented by a magnetic configuration of a small volume of ferromagnetic material and its magnetic state that can be measured during a read-back operation. The MRAM typically includes a two-dimensional array of memory cells wherein each cell comprises one magnetic tunnel junction (MTJ) (or magnetoresistive (MR)) element that can store at least one bit of data, one selection transistor (T) an intersecting conductor lines (so-called 1T-1MTJ design).

Conventional MTJ element represents a patterned thin film multilayer that includes at least a pinned magnetic layer and a free magnetic layer separated from each other by a thin tunnel barrier layer. The free layer has two stable directions of magnetization that are parallel or anti-parallel to the fixed direction of the magnetization in the pinned layer. Resistance of the MTJ depends on a mutual orientation of the magnetizations in the free and pinned layers and can be effectively measured. A resistance difference between the parallel and anti-parallel states of the MTJ can exceed 600% at room temperature.

The direction of the magnetization in the free layer may be changed from parallel to anti-parallel or vice-versa by applying two orthogonal magnetic fields to the selected MTJ, by passing a spin-polarized current through the selected junction in a direction perpendicular to the junction plane, or by using a hybrid switching mechanism that assumes a simultaneous application of the external magnetic field and spin-polarized current to the selected MTJ. The hybrid switching mechanism looks the most attractive among all others since it can provide good cell selectivity in the array, relatively low switching current and high write speed.

FIGS. 1A and 1B show a schematic cross-sectional and top down views of MRAM cell 10 employing the hybrid switching mechanism according to a prior art disclosed in U.S. Pat. No. 7,006,375 (Covington). The cross-section was taken alone the line 1A-1A shown in the FIG. 1B. The memory cell 10 includes a semiconductor wafer 11 with a selection transistor 12, MTJ element 21, a word line 16 and a bit line 19 that are orthogonal to each other (1T-IMTJ design). The bit line 19 and the MTJ element 21 arc connected in series to a source region 13 of the selection transistor 12. The MTJ element 21 includes a pinned magnetic layer 22 with a fixed in-plane magnetization direction (shown by an arrow), a free magnetic layer 23 with a changeable in-plane magnetization direction (shown by arrows), a thin tunnel barrier layer 24 positioned between the free 23 and pinned 22 layers, and a pinning anti-ferromagnetic layer 25 exchange coupled with the pinned layer 22. The MTJ element 21 has an elliptical shape with a major axis of the ellipse being oriented in parallel to the word line 19. An easy magnetic axis of the pinned and free layers coincides with the major axis. The transistor 12 comprises a gate 15 having a width W of about a width of the MTJ element 21 (W=F). A drain region 14 of the transistor 12 is connected to a ground line 18 through a contact plug 17.

To write a data to the MTJ element 21, a bias electric current I_{B} is applied to the bit line 19. The current I_{B} induces a magnetic bias field H_{B} that affects the free layer 23 along its hard magnetic axis. The field H_{B} forces the magnetization direction in the free layer 23 from its equilibrium state that is parallel to the major axis of the MTJ element 21. By applying a voltage to the gate 15 through the word line 16 the selection transistor 12 can be turned on. The transistor 12 delivers a spin-polarized current I_{S} to the MTJ element 21. The current I_{S} running through the element 21 produces a spin momentum transfer that together with the bias field H_{B} provides a reversal of the magnetization direction in the free layer 23. The magnetization direction in the free layer 23 is controlled by a direction of the spin-polarized current I_{S}. Magnitude of the spin-polarized current I_{S} required to reverse the magnetization in the free layer 23 depends on the strength of the bias field H_{B} that tilts the magnetization direction in the free layers relatively its equilibrium state. The switching current I_{S} can be reduced more than twice by the relatively small bias magnetic field H_{B}.

The MTJ with in-plane magnetization direction requires a high magnitude of the switching current I_{S} even with applied magnetic bias field H_{B}. Magnitude of the spin-polarized current I_{S} defines a write speed of the memory cell; the speed increases with the current. The spin-polarized current I_{S} of the cell 10 is limited by a saturation current of the transistor 12 that is proportional to a gate width W. The selection transistor 12 has the gate width W comparable to the width F of the elliptical MTJ element 21. This gate width is incapable to deliver the required magnitude of the current I_{S}. To overcome the above obstacles the gate width W of the transistor 12 needs to be substantially increased. However that will result in considerable increase of memory cell size and in MRAM density reduction.

Majority of the current MRAM designs uses the free and pinned layers made of magnetic materials with in-plane anisotropy. The in-plane MRAM (i-MRAM) suffers from a large cell size, low thermal stability, poor scalability, necessity to use MTJ with a special elliptical shape, and from other issues, which substantially limit a possibility of i-MRAM application at technology nodes below 90 nm.

MRAM with a perpendicular direction of the magnetization in the free and pinned layers (p-MRAM) does not suffer from the above problems since perpendicular magnetic materials have a high intrinsic crystalline anisotropy. The high anisotropy provides the p-MRAM with the excellent thermal stability and scalability, and with a possibility to use junctions of any shape. Nevertheless the existing p-MRAM designs have a large cell size and require a relatively high switching current.

What is needed is a simple design of p-MRAM having high switching speed at low current, small cell size, high capacity and excellent scalability.

### SUMMARY

The present application provides a three-dimensional magnetic random access memory (3D MRAM) with a perpendicular magnetization for high-speed writing.

In accordance with one embodiment a magnetic random access memory comprises a substrate, a plurality of transistors formed on the substrate and arranged in a matrix, each transistor comprising a gate width; a memory layer formed on the substrate and comprising a plurality of memory cells arranged in the matrix, each memory cell overlaid a transistor and comprising a plurality of magnetoresistive elements jointly electrically coupled to the transistor at first terminals, each magnetoresistive element comprising an element width, a pinned ferromagnetic layer comprising a fixed magnetization direction directed substantially perpendicular to the substrate, a free ferromagnetic layer comprising a reversible magnetization direction directed substantially perpendicular to the substrate in an equilibrium state, a tunnel barrier layer disposed between the pinned and free ferromagnetic layers; and a plurality of parallel conductive lines disposed above the memory layer and independently electrically coupled to second terminals of the magnetoresistive elements, wherein the gate width is substantially larger than the element width.

In accordance with another embodiment a method of writing to a magnetic random access memory includes providing a substrate, a transistor formed on the substrate and comprising a gate width, a memory cell disposed above the transistor and comprising a plurality of magnetoresistive elements jointly electrically coupled to the transistor at first terminals, each magnetoresistive element comprising an element width, a pinned ferromagnetic layer disposed adjacent to a first terminal and comprising a fixed magnetization direction directed substantially perpendicular to the substrate, a free ferromagnetic layer disposed adjacent to a second terminal and comprising a reversible magnetization direction directed substantially perpendicular to the substrate in an equilibrium state, a tunnel barrier layer disposed between the pinned and free ferromagnetic layers, and a plurality of parallel conductive lines independently electrically coupled to second terminals of the magnetoresistive elements; driving a bias current through a conductive line for producing a bias magnetic field directed along a hard magnetic axis of the free ferromagnetic layer; and driving a spin-polarized current through the magnetoresistive element between the first and second terminals in a direction perpendicular to the substrate for producing a spin momentum transfer. The magnetization direction of the free ferromagnetic layer is reversed by a joint effect of the bias and spin-polarized currents applied simultaneously.

### BRIEF DESCRIPTION OF THE DRAWINGS

FIG. 1A illustrates a schematic cross-section view of MRAM cell with in-plane magnetization in free and pinned layers employing a hybrid write mechanism according to a prior art.

FIG. 1B is a schematic top-down view of the MRAM cell of FIG. 1A. FIG. 2A is a schematic cross-sectional view of a perpendicular MRAM cell with a hybrid write mechanism according to an embodiment of the present application.

FIG. 2B is a schematic top-down view of the perpendicular MRAM cell of FIG. 2A.

FIG. 3 is a schematic view of a perpendicular MRAM cell with a bilayer structure of free and pinned layers according to another embodiment of the present application.

FIG. 4A is a schematic top-down view of two adjacent MRAM cells according to yet another embodiment of the present application.

FIG. 4B is a schematic cross-sectional view of two adjacent MRAM cells of FIG. 4A.

FIG. 5 is a schematic cross-sectional view of a three dimensional perpendicular MRAM with two memory layers according to yet another embodiment of the present application.

FIG. 6 is a circuit illustrating a first interconnection scheme between magnetoresistive elements and a selection transistor in a three-dimensional MRAM cell.

FIG. 7 is a circuit diagram illustrating a second interconnection scheme between magnetoresistive elements and a selection transistor in a three-dimensional MRAM cell.

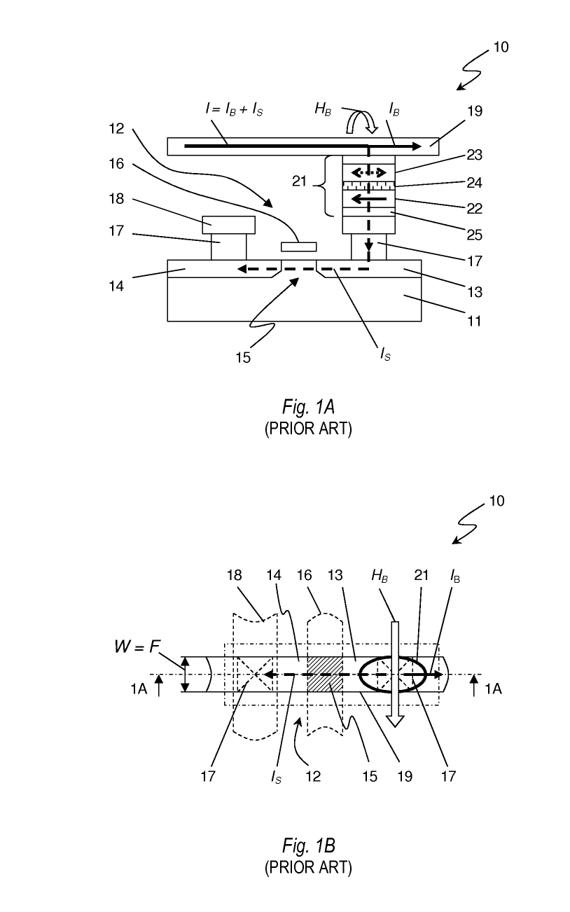

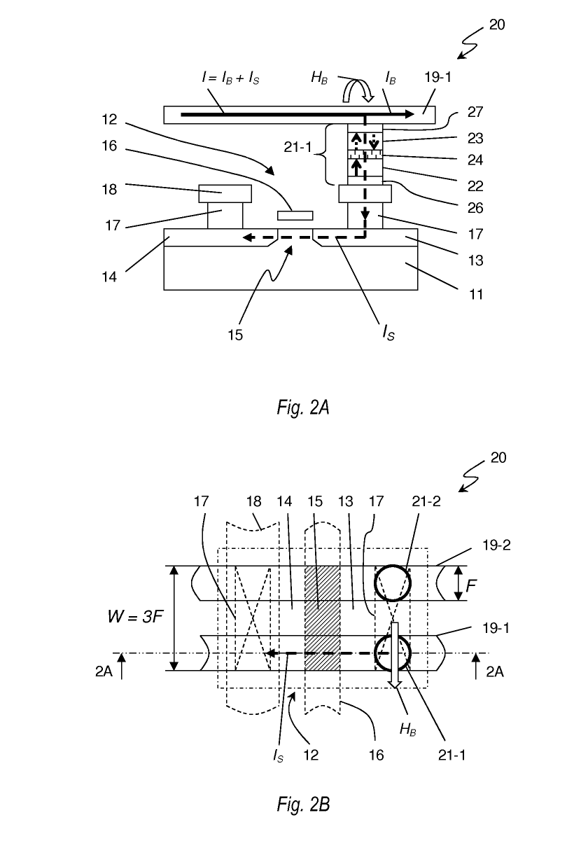

### DETAILED DESCRIPTION

In the following detailed description of the embodiments, reference is made to the accompanying drawings that form a part hereof, and in which are shown be way of illustration specific embodiments in which the application may be practiced. It is understood that other embodiments may be utilized and structural changes may be made without departing from the scope of the present application.

The leading digits of reference numbers appearing in the Figures generally corresponds to the Figure number in which that component is first introduced, such that the same reference number is used throughout to refer to an identical component which appears in multiple Figures.

FIG. 2A show a schematic cross-sectional view of memory cell 20 according to an embodiment of the present application. The cross-section is taken along line 2A-2A that is shown in the FIG. 2B. The memory cell 20 comprises a semiconductor substrate 11 with a selection transistor 12, a MTJ (or magnetoresistive) element 21, a word line 16 and a bit line 19; the lines 16 and 19 overlap each other. The MTJ element 21 comprises a pinned layer 22 with a fixed magnetization direction (shown by an arrow) directed substantially perpendicular to a layer plane, a free layer 23 with a changeable magnetization direction (shown by two arrows) directed substantially perpendicular to a layer plane in its equilibrium state, a tunnel barrier layer 24 sandwiched between the pinned 22 and free 23 layers, a seed layer 26 and a cap layer 27. The free layer 23 has two stable directions of the magnetization in its equilibrium state: up or down. The MTJ element 21 is electrically connected to the bit line 19 and to the source region 13 of the transistor 12 through a contact plug 17. The word line 16 is coupled to the gate region 15 through an insulator layer (not shown). The memory cell 20 comprises two MTJ elements 21-1 and 21-2, and two parallel bit lines 19-1 and 19-2. The MTJ element 21-1 is electrically connected to the line 19-1 at one end adjacent to the free layer 23. Respectively, the MTJ element 21-2 is connected to the line 19-2. Both the MTJ elements at their second ends are jointly connected to the source region 13 of the transistor 12 through the contact plug 17. The transistor 12 has a footprint size comparable with the size of the cell 20 (shown by a dash-dot line) and the gate width of about W=3F, where F is a diameter of the MTJ elements. The large gate width W provides the transistor 12 with a high saturation current, which is important for high-speed writing.

The memory cell 20 has a 1T-2MTJ (one transistor-two MTJs) design. Number of the MTJ elements in the cell 20 can be any. Each MTJ element of the memory cell 20 has a unique combination of the bit and word lines that provides its selection in the MRAM array. For instance, to write data to the MTJ element 21-1 the bias current I_{B} needs to be run in the bit line 19-1 and the spin-polarized current I_{S} should run through the element in direction perpendicular to its plane. The spin-polarized current I_{S} is controlled by the word line 16 that intersects the bit line 19-1 in vicinity of the MTJ element 21-1. Combined effect of the bias I_{B} and spin-polarized I_{S} currents can reverse the magnetization direction in the free layer 23 of the element 21-1.

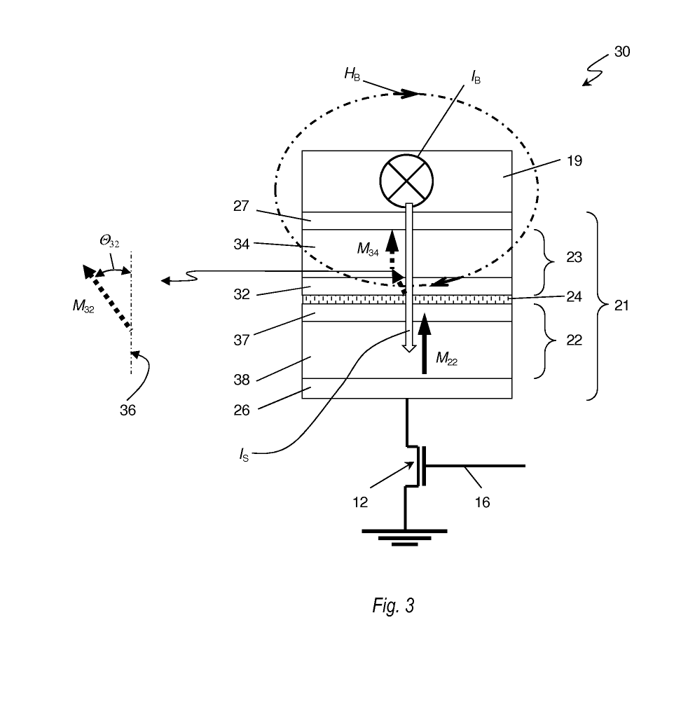

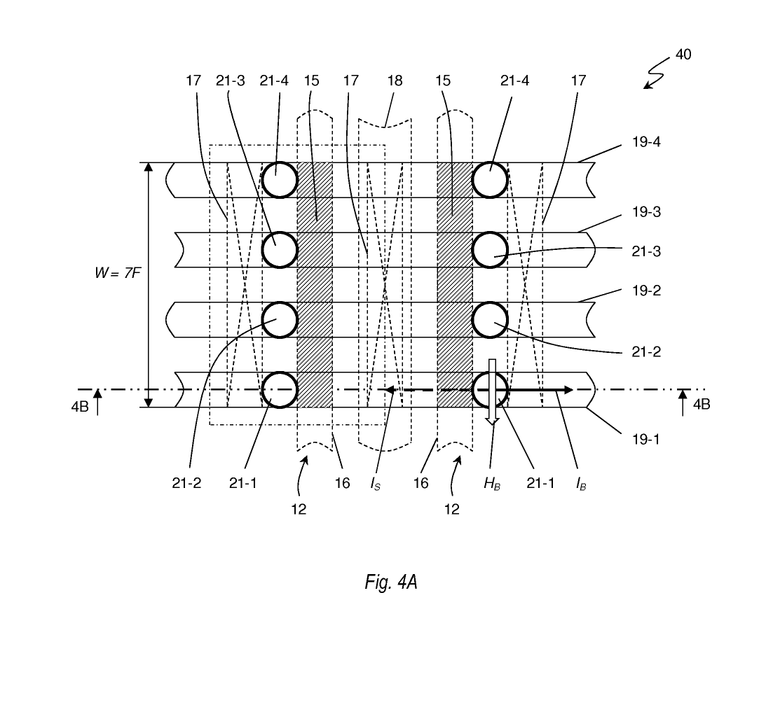

In some embodiments the MTJ element 21 has a multilayer structure of the pinned 22 and free 23 layers. The FIG. 3 illustrates a memory cell 30 according to another embodiment of with a bilayer structure of the pinned 22 and free 23 layers. The free layer 23 comprises a storage layer 34 having a perpendicular anisotropy and a first coercivity, and a soft magnetic underlayer 32 having a second coercivity. The soft magnetic underlayer 32 is disposed between the tunnel barrier layer 24 and the storage layer 34 and is substantially magnetically coupled to the storage layer 34. The coercivity of the storage layer 34 is significantly higher than the coercivity of the soft magnetic underlayer 32. The pinned layer 22 can comprise the reference layer 38 with a perpendicular anisotropy having a third coercivity, and a spin-polarizing layer 37 with a fourth coercivity. The coercivity of the reference layer 38 is substantially higher than the coercivity of the storage layer 34. The spin-polarizing layer 37 is disposed between the tunnel barrier layer 24 and the reference layer 38 and is substantially magnetically coupled to the reference layer 38. The soft magnetic underlayer 32 can be made of a soft magnetic material with perpendicular or in-plane crystalline anisotropy. However due to a strong magnetic coupling to the storage layer 34 the direction of the magnetization in the soft magnetic underlayer 32 can be maintained perpendicular to layer plane in its equilibrium state.

A pulse of the bias current I_{S} running in the bit line 19 induces a bias magnetic field H_{B} that is applied to the free layer 23 along its hard axis. The field H_{B} can tilt the magnetization M₃₂ in the soft magnetic underlayer 32 on the angle Θ₃₂ but does not change the direction of the magnetizations M₂₂ and M₃₄ in the pinned 22 and storage 34 layers, respectively. The angle Θ₂₂ depends on the bias current magnitude, on thickness and magnetic properties of the soft magnetic underlayer 32 and the storage layer 34, and on the strength of the magnetic coupling between them. Tilting of the magnetization M₃₂ in the soft magnetic underlayer 32 can provide a significant reduction of the magnitude of spin-polarized current pulse I_{S} that is required to reverse the magnetization direction in the storage layer 34. The spin-polarizing layer 37 offers a substantial spin polarization polarization of the switching current that is also important for reduction of I_{S} magnitude. A material of the spin-polarizing layer can have perpendicular or in-plane anisotropy. The direction of the magnetization in the spin-polarizing layer 37 may not change under the bias field H_{B} due to its strong magnetic coupling with the reference layer 38. The magnetization directions in the soft magnetic underlayer 32 and in the spin-polarizing layer 37 are substantially collinear (parallel or anti-parallel) in the equilibrium state. That is important for providing a high output signal during read operation. The saturation current of the transistor 12 does not limit the magnitude of the spin-polarized current I_{S} since the transistor has a large gate width W. At the same time, the bias field H_{B} can offer a significant reduction of the spin-polarized current I_{S} and an additional opportunity of the write speed increase.

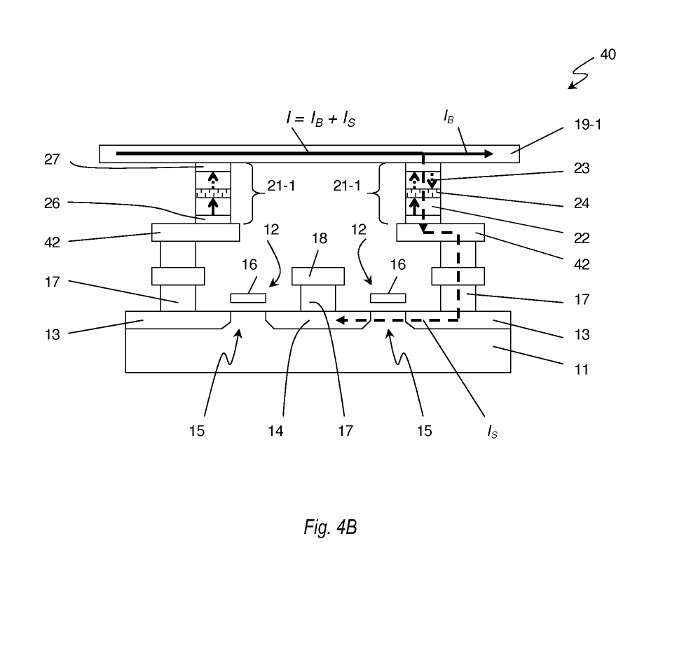

FIGS. 4A and 4B illustrate two memory cells 40 according to yet another embodiment of the present application wherein one of the cells is shown by a dash-dot line. The cells have a common ground line 18 connected to the common drain region 14 of two selection transistors 12. Footprints of the selection transistor 12 and the memory cell 40 coincide. The cells 40 have 1T-4MTJ design with four MTJ elements 21-1, 21-2, 21-3 and 21-4, and four parallel bit lines 19-1, 19-2, 19-3 and 19-4 separately connected to the appropriate elements at their second ends adjacent to the free layer 23. All MTJ elements of the memory cells 40 are jointly connected at their first ends adjacent to the pinned layer 24 to the source region 13 of the proper transistor 12 through the contact plug 17. Selection of a MTJ element in the MRAM array is provided by unique combination of bit and word lines overlapping at the MTJ location. The transistors 12 have a gate width of about W=7F and can deliver a considerable spin-polarized current to the MTJ elements 21 for high-speed writing.

FIG. 4B shows a schematic cross-sectional view of the cells 40 given in FIG. 4A. The cross section was taken along 4B-4B line. Elements of the cells 40 have functions similar to those shown in FIGS. 2A and 2B. Each of the cells 40 additionally includes a local conductor line 42. The MTJ elements 21 of the memory cell 40 are jointly electrically connected to the source region 13 of the proper transistor 12.

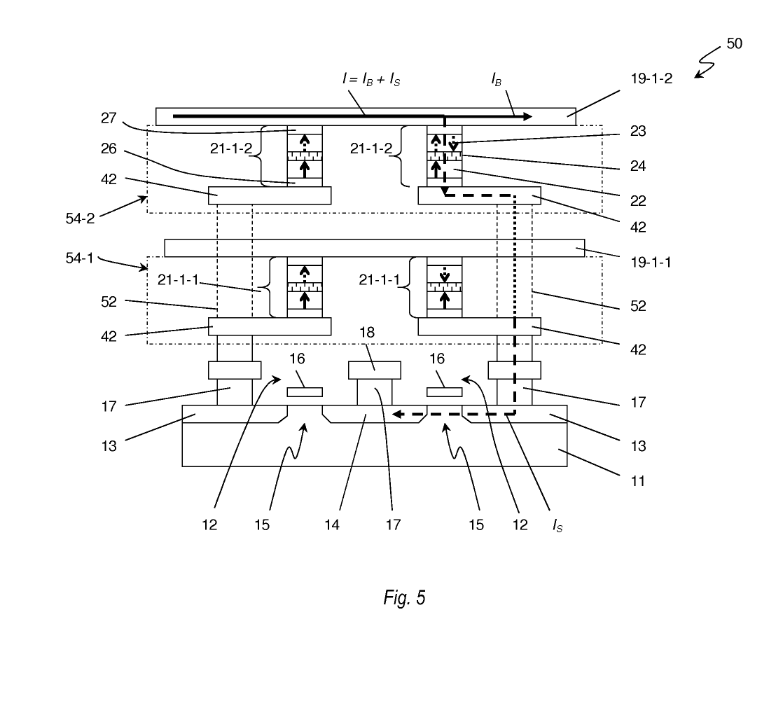

FIG. 5 shows a schematic cross-sectional view of two cells 50 of three-dimensional MRAM according to yet another embodiment of the present application. Each of the cells 50 comprises two memory layers 54-1 and 54-2 that include a plurality of MTJ elements 21, and two conductor layers 19-1-1 and 19-1-2 disposed above the memory layers 54-1 and 54-2, respectively. Each of the conductor layers comprises a plurality of parallel bit lines 19. The bit lines 19 disposed in the different conductor layers are parallel to each other and overlap the word lines 16. Selection of the MTJ in the 3D-MRAM is provided by a unique combination of the word line 16, the bit line 19 and the memory layer. Elements of the cells 50 have functions similar to those in the FIGS. 2A and 2B. The three- dimensional memory cell 50 provides a possibly of substantial MRAM density increase. The MTJ elements of the 3D-MRAM can have different interconnection schemes.

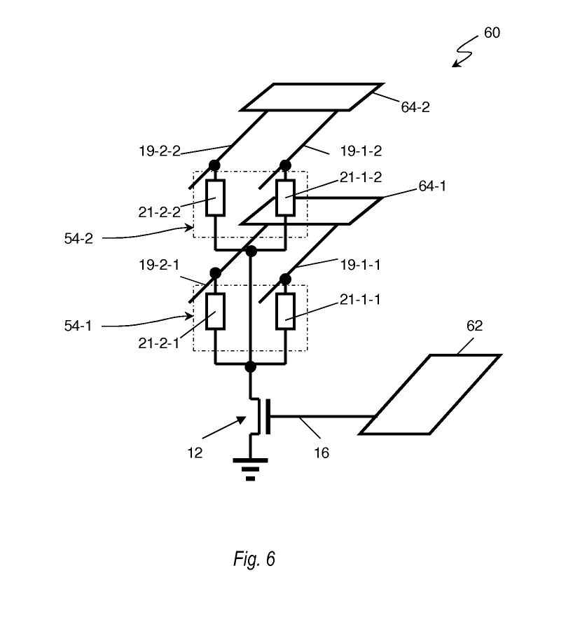

FIG. 6 shows a circuit diagram of 3D-memory cell 60 according to still another embodiment of the present application. The memory cell 60 has 1T-2MTJ-2L design, where 2L are two memory layers. It includes one selection transistor 12, two MTJ elements 21 per memory layer and two memory layers 54-1 and 54-2. The number of MTJ elements in the memory layer and the number of memory layers can be any. All MTJ elements 21 of the memory cell 60 are jointly connected to the source terminal of the selection transistor 12 at their first ends that are adjacent to the pinned layer 22 and separately connected to an appropriate word line 19 at their second ends that are adjacent to the free layer 23 (FIG. 5). The word line 16 is connected to a word line circuitry 62. The bit lines 19 are connected to the bit line circuitry 64. The bit line circuitry can includes several bit line drivers with one driver per conductor layer. For instance, the lines 19-1-1 and 19-2-1 of the bottom conductor layer are connected to the bit line driver 64-1 and the bit lines 19-1-2 and 19-2-2 of the top conductor layer are connected to the bit line driver 64-2. The number of the bit line drivers can be any.

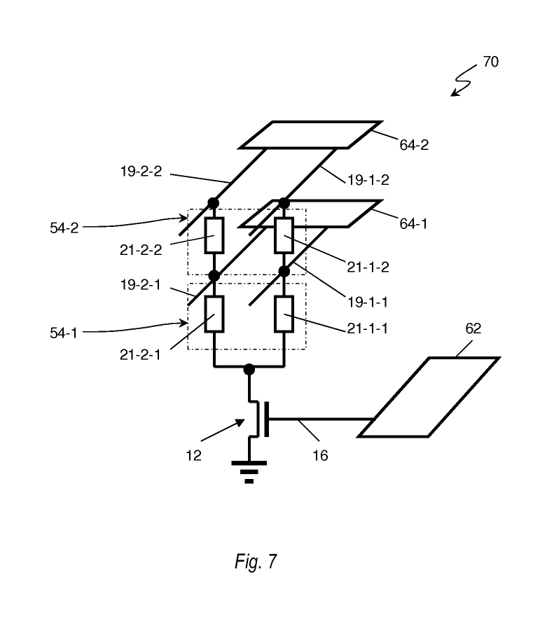

FIG. 7 shows a circuitry diagram of 3D-memory cell 70 according to still another embodiment of the present application. The memory cell 70 has 1T-2MTJ-2L design but distinguishes from the cell 60 shown in the FIG. 6 by connection scheme between the overlaying MTJ elements 19 of the different memory layers 54-1 and 54-2. The MTJ elements 19 of the layers 54-1 and 54-2 are connected in series to each other to form columns of the MTJ elements. The columns of the MTJ elements are jointly connected to the selection transistor 12.

There is wide latitude for the choice of materials and their thicknesses within the embodiments.

The pinned layer 22 has a thickness of about 10-100 nm and more specifically of about 25-50 nm and coercivity measured along its easy axis above than 1000 Oe and more specifically of about 2000-5000 Oe. The layer 22 is made of magnetic material with a perpendicular anisotropy such as Co, Fe or Ni-based alloys or their multilayers such as Co/Pt, Co/Pd, Co/Au, CoFe/Pt, Fe/Pt, Fe/Pd, Ni/Co or similar.

The free layer 23 has a thickness of about 1-30 nm and more specifically of about 5-15 nm and coercivity less than 1000 Oe and more specifically of about 100-300 Oe. The layer 23 is made of soft magnetic material with a perpendicular anisotropy such as Co, Fe or Ni-based alloys or multilayers such as Co/Pt, Co/Pd, Co/Au, CoFe/Pt, Fe/Pt, Fe/Pd, Ni/Co or similar.

The tunnel barrier layer 24 has a thickness of about 0.5-25 nm and more specifically of about 0.5-1.5 nm. The tunnel barrier layer is made of MgO, Al₂O₃, Ta₂O₅, TiO₂, Mg-MgO and similar materials or their based laminates.

The seed 26 and cap 27 layers have a thickness of 1-100 nm and more specifically of about 5-25 nm. The layers are made of Ta, W, Ti, Cr, Ru, NiFe, NiFeCr, PtMn, IrMn or similar conductive materials or their based laminates.

The conductor lines 18 and 19 are made of Cu, Al, Au, Ag, AlCu, Ta/Au/Ta, Cr/Cu/Cr and similar materials or their based laminates.

The soft magnetic underlayer 32 is 0.5-5 nm thick and is made of a soft magnetic material with a substantial spin polarization and coercivity of about 1-200 Oe such as CoFe, CoFeB, NiFe, Co, Fe, CoPt, FePt, CoPtCu, FeCoPt and similar or their based laminates such as CoFe/Pt, CoFeB/Pd and similar. The material of the soft magnetic underlayer 74 can have either in-plane or perpendicular anisotropy.

The storage layer 34 has a thickness of 5-25 nm and more specifically of about 8-15 nm; and coercivity less than 1000 Oe and more specifically of about 200-500 Oe. The storage layer 76 is made of magnetic material with a substantial perpendicular anisotropy such as Co, Fe or Ni-based alloys or multilayers such as Co/Pt, Co/Pd, Co/Au, CoFe/Pt, Fe/Pt, Fe/Pd, Ni/Co or similar. The spin-polarizing layer 37 has a thickness of 0.5-5 nm and is made of a soft magnetic material with a coercivity of about 1-200 Oe and a substantial spin polarization such as CoFe, CoFeB, NiFe, Co, Fe, CoPt, FePt, CoPtCu, FeCoPt and similar or their based laminates such as CoFe/Pt, CoFeB/Pd and similar. The material of the spin-polarizing layer 37 can have either in-plane or perpendicular anisotropy.

The reference layer 38 has a thickness of 10-100 nm and more specifically of about 20-50 nm; and coercivity above 1000 Oe and more specifically of about 2000-5000 Oe. The reference layer 38 is made of a magnetic material with a substantial perpendicular anisotropy such as Co, Fe or Ni-based alloys or multilayers such as Co/Pt, Co/Pd, Co/Au, CoFe/Pt, Fe/Pt, Fe/Pd, Ni/Co or similar.

It is understood that the above description is intended to be illustrative, and not restrictive. Many other embodiments will be apparent to those of skill in the art upon reviewing the above description. The scope of the application should be, therefore, determined with reference to the appended claims, along with the full scope of equivalents to which such claims are entitled.

1. A magnetic memory cell comprising:
a transistor disposed on a substrate and comprising a gate width and a terminal;
a plurality of magnetoresistive elements disposed above the substrate, each magnetoresistive element comprising an element width, a pinned magnetic layer comprising a fixed magnetization direction directed substantially perpendicular to the substrate, a free magnetic layer comprising a reversible magnetization direction directed substantially perpendicular to the substrate in its equilibrium state, and a tunnel barrier layer disposed between the pinned layer and the free layer; and
a plurality of parallel conductive lines overlapping the terminal and independently electrically coupled to the plurality of magnetoresistive elements at their first ends adjacent to the free magnetic layer,
wherein the plurality of magnetoresistive elements is jointly electrically coupled to the terminal of the transistor at their second ends; and
wherein the gate width is more than two times larger than the element width.

2. The magnetic memory cell of claim 1 wherein the free magnetic layer comprises:
a storage layer comprising a magnetic material having a perpendicular anisotropy and a first coercivity; and
a soft magnetic layer comprising a second coercivity, the soft magnetic layer is disposed between the tunnel barrier layer and the storage layer, and magnetically exchange coupled to the storage layer,
wherein the first coercivity is at least two times larger than the second coercivity.

3. The magnetic memory cell of claim 2 wherein the soft magnetic layer comprises a magnetic material having an in-plane anisotropy.

4. The magnetic memory cell of claim 1 wherein the pinned magnetic layer comprises:
a reference layer comprising a magnetic material having a perpendicular anisotropy; and
a spin-polarizing layer disposed between the tunnel barrier layer and the reference layer,
wherein the spin-polarizing layer is magnetically exchange coupled to the reference layer.

5. The magnetic memory cell of claim 4 wherein the spin-polarizing layer comprises a magnetic material having an in-plane anisotropy.

6. The magnetic memory cell of claim 2 wherein the soft magnetic layer comprises a magnetic material having a perpendicular anisotropy.

7. The magnetic memory cell of claim 4 wherein the spin-polarizing layer comprises a magnetic material having a perpendicular anisotropy.

8. The magnetic memory cell of claim 1 wherein the magnetization direction of the free magnetic layer is reversed by a joint effect of a spin-polarizing current running through a magnetoresistive element in a direction perpendicular to the substrate and a bias current running through a parallel conductive line coupled to the magnetoresistive element.
